(19) United States
(12) Patent Application Publication
(10) Pub. No.: US 2024/0426899 A1
(43) Pub. Date: Dec. 26, 2024

(54) SEMICONDUCTOR INTEGRATED CIRCUIT DEVICE, VEHICLE-MOUNTED APPLIANCE, AND VEHICLE

(71) Applicant: ROHM CO., LTD., Kyoto (JP)

(72) Inventor: Takumi YAMADA, Kyoto (JP)

(21) Appl. No.: 18/824,489

(22) Filed: Sep. 4, 2024

Related U.S. Application Data
(63) Continuation of application No. PCT/JP2023/002640, filed on Jan. 27, 2023.

(30) Foreign Application Priority Data
Mar. 11, 2022 (JP) 2022-037764

(51) Int. Cl. G01R 31/28; G01R 31/317; G01R 31/3187

(52) U.S. Cl. CPC G01R 31/2856; G01R 31/31721; G01R 31/3187

(57) ABSTRACT

A semiconductor integrated circuit device includes a logic circuit, a holding circuit, and a test circuit. The holding circuit is configured to hold setting information output from the logic circuit when triggered by an event after the start-up of the semiconductor integrated circuit device. The test circuit is configured to execute a BIST on the logic circuit after completion of the holding.

### CROSS-REFERENCE TO RELATED APPLICATIONS

This nonprovisional application is a continuation application of International Patent Application No. PCT/JP2023/002640 filed on Jan. 27, 2023, which claims priority to Japanese Patent Application No. 2022-037764 filed in Japan on Mar. 11, 2022, the entire contents of which are hereby incorporated by reference.

### BACKGROUND OF THE INVENTION

### 1. Technical Field

The disclosure herein relates to a semiconductor integrated circuit device, and also to a vehicle-mounted appliance and a vehicle incorporating a semiconductor integrated circuit device.

### 2. Description of Related Art

Conventionally, semiconductor integrated circuit devices having a logic circuit are used in various applications.

An example of known technology related to what has just been mentioned is seen in JP-A-2017-53825.

### BRIEF DESCRIPTION OF THE DRAWINGS

FIG. 1 is a block diagram showing a configuration of a semiconductor integrated circuit device according to a first embodiment.

FIG. 2 is a diagram showing state transitions in the semiconductor integrated circuit device shown in FIG. 1.

FIG. 3 is a block diagram showing a configuration of a semiconductor integrated circuit device according to a second embodiment.

FIG. 4 is a diagram showing state transitions in the semiconductor integrated circuit device shown in FIG. 3.

FIG. 5 is an exterior view of a vehicle.

### DESCRIPTION OF EMBODIMENTS

### Semiconductor Integrated Circuit Device (First Embodiment)

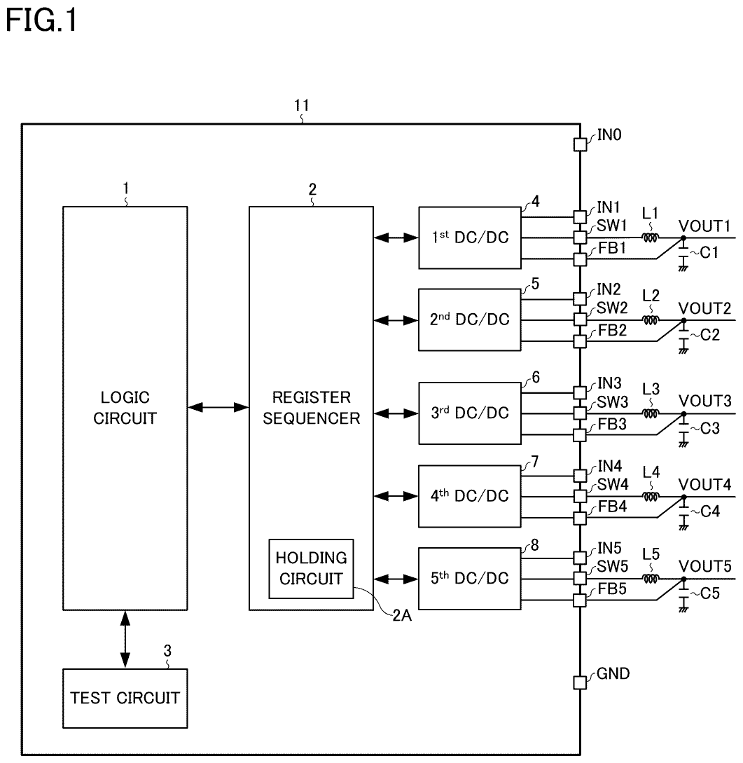

FIG. 1 is a block diagram showing a configuration of a semiconductor integrated circuit device according to a first embodiment. The semiconductor integrated circuit device 11 of this embodiment is a PMIC (power management IC).

The semiconductor integrated circuit device 11 includes a logic circuit 1, a register sequencer 2, a test circuit 3, first to fifth DC-DC converters 4 to 8, and terminals IN0 to IN5, SW1 to SW5, and FB1 to FB5.

An input voltage is fed to the terminal IN0. A ground voltage lower than the input voltage fed to the terminal IN0 is fed to a terminal GND. The semiconductor integrated circuit device 11 is driven by a voltage between the input voltage fed to the terminal IN0 and the ground voltage fed to the terminal GND.

The logic circuit 1 performs start-up/shut-down sequence control for the first to fifth DC-DC converters 4 to 8 via a register sequencer 2. The logic circuit 1 outputs setting information related to the start-up/shut-down control for the first to fifth DC-DC converters 4 to 8 to the register sequencer 2. The register sequencer 2 controls the first to fifth DC-DC converters 4 to 8 based on the setting information output from the logic circuit 1.

The register sequencer 2 includes a holding circuit 2A. When triggered by a state transition after the start-up of the semiconductor integrated circuit device 11, the holding circuit 2A holds the setting information output from the logic circuit 1.

The test circuit 3 executes a BIST with respect to the logic circuit 1.

The first DC-DC converter 4, together with an inductor L1 and a capacitor C1, both externally connected, forms a buck (step-down) switching regulator. The voltage fed to the terminal IN1 is converted into a pulsating switching voltage by the first DC-DC converter 4. The switching voltage output from the terminal SW1 is smoothed by the inductor L1 and the capacitor C1 to be converted into an output voltage VOUT1. The output voltage VOUT1 is lower than the voltage fed to terminal IN1. The output voltage VOUT1 is fed to the terminal FB1. The first DC-DC converter 4 monitors the output voltage VOUT1 to perform feedback control.

The second to fifth DC-DC converters 5 to 8 have a configuration similar to that of the first DC-DC converter 4, and therefore no overlapping description will be repeated.

Unlike in this embodiment, some or all of the first to fifth DC-DC converters 4 to 8 do not necessarily have to be each a component of a buck switching regulator. For example, some or all of the first to fifth DC-DC converters 4 to 8 can be each a component of a boost switching regulator, a component of a boost/buck switching regulator, a component of a linear power circuit, or the like. While the first to fifth DC-DC converters 4 to 8 may have a configuration similar to each other as in this embodiment, they can also be a combination of a plurality of types of power supply circuits (for example, two types of power supply circuits comprising a component of a buck switching regulator and a component of a linear power supply circuit).

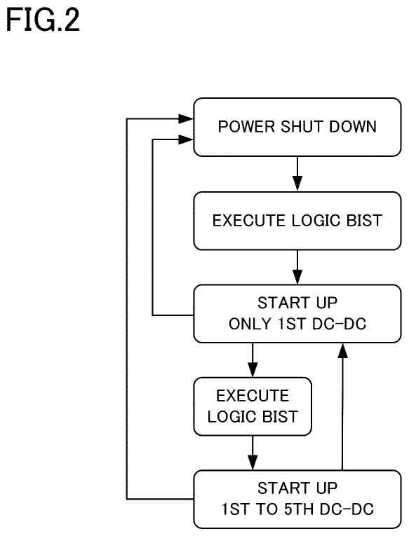

FIG. 2 is a diagram showing state transitions in the semiconductor integrated circuit device 11. Here, as one example, it is assumed that the semiconductor integrated circuit device 11 can, after its start-up, take two states: a state where only the first DC-DC converter 4 among the first to fifth DC-DC converters 4 to 8 is started up; and a state where all the first to fifth DC-DC converters 4 to 8 are started up.

When a transition is made from a state where the power is shut down (no input voltage is fed to the terminal IN0) to a state where the power is on (the input voltage is fed to the terminal IN0), the test circuit 3 executes the BIST on the logic circuit 1. After the BIST on the logic circuit 1 is complete, the start-up of the semiconductor integrated circuit device 11 is complete.

In the example shown in FIG. 2, after the BIST on the logic circuit 1 is complete, the semiconductor integrated circuit device 11 is in the state where only the first DC-DC converter 4 among the first to fifth DC-DC converters 4 to 8 is started up.

After that, also when, under the control of the logic circuit 1, a transition is made from the state where only the first DC-DC converter 4 among the first to fifth DC-DC converters 4 to 8 is started up to the state where all the first to fifth DC-DC converters 4 to 8 are started up, the test circuit 3 executes the BIST on the logic circuit 1.

More specifically, when a transition takes place from the state where only the first DC-DC converter 4 among the first to fifth DC-DC converters 4 to 8 is started up to the state where all the first to fifth DC-DC converters 4 to 8 are started up, the holding circuit 2A, triggered by this transition, holds the setting information (the setting information in the state where only the first DC-DC converter 4 among the first to fifth DC-DC converters 4 to 8 is started up) output from the logic circuit 1. In this way, the semiconductor integrated circuit device 11 can continue to normally output the output voltage VOUT1 using the inductor L1 and the capacitor C1.

Then, after the setting information output from the logic circuit 1 is held by the holding circuit 2A, the test circuit 3 executes the BIST on the logic circuit 1. When the logic BIST is complete, the holding circuit 2A ceases to hold the setting information output from the logic circuit 1. As a result, the semiconductor integrated circuit device 11 can output the output voltages VOUT1 to VOUT5 using the inductors L1 to L5 and the capacitors C1 to C5.

The semiconductor integrated circuit device 11 can increase the frequency of executing the logic BIST, and this helps improve reliability against faults.

The test circuit 3 can be configured to execute the BIST on the logic circuit 1 every time a transition is made from the state where only the first DC-DC converter 4 among the first to fifth DC-DC converters 4 to 8 is started up to the state where all the first to fifth DC-DC converters 4 to 8 are started up. In this way, it is possible to further increase the frequency of executing the logic BIST.

Conversely, the test circuit 3 can be configured to perform the BIST on the logic circuit 1 only some of the times that a transition is made from the state where only the first DC-DC converter 4 among the first to fifth DC-DC converters 4 to 8 is started up to the state where all the first to fifth DC-DC converters 4 to 8 are started up. In this way, it is possible to adjust the frequency of executing the logic BIST. Performing the BIST at a reduced frequency can reduce the average time required for state transitions.

As a specific method for reducing the frequency of BIST execution, a counter can be provided to count the number of transitions from the state where only the first DC-DC converter 4 among the first to fifth DC-DC converters 4 to 8 is started up to the state where all the first to fifth DC-DC converters 4 to 8 are started up; each time the counter has counted up to a predetermined value, the logic BIST can be executed and the counter can be reset.

As another specific method for reducing the frequency of BIST execution, the semiconductor integrated circuit device 11 can be configured to receive after its start-up an enable signal related to a logic BIST so that the logic BIST after the start-up of the semiconductor integrated circuit device 11 is executed only when a transition as mentioned above takes place during the period in which the semiconductor integrated circuit device 11 is receiving the enable signal.

When, in the state where only the first DC-DC converter 4 among the first to fifth DC-DC converters 4 to 8 is started up, the input voltage ceases to be fed to the terminal IN0, a transition is made to a state where the power is shut down.

When, in the state where all the first to fifth DC-DC converters 4 to 8 are started up, the input voltage ceases to be fed to the terminal IN0, a transition is made to a state where the power is shut down.

In the example shown in FIG. 2, when a transition is made from the state where all the first to fifth DC-DC converters 4 to 8 are started up to the state where only the first DC-DC converter 4 among the first to fifth DC-DC converters 4 to 8 is started up, the test circuit 3 does not execute the BIST on the logic circuit 1.

Unlike the example shown in FIG. 2, the test circuit 3 may execute the BIST on the logic circuit 1 when a transition is made from the state where all the first to fifth DC-DC converters 4 to 8 are started up to the state where only the first DC-DC converter 4 among the first to fifth DC-DC converters 4 to 8 is started up. In this case, the test circuit 3 may keep from executing the BIST on the logic circuit 1 when a transition is made from the state where only the first DC-DC converter 4 among the first to fifth DC-DC converters 4 to 8 is started up to the state where all the first to fifth DC-DC converters 4 to 8 are started up. Or, the test circuit 3 may execute the BIST on the logic circuit 1 also when a transition is made from the state where only the first DC-DC converter 4 among the first to fifth DC-DC converters 4 to 8 is started up to the state where all the first to fifth DC-DC converters 4 to 8 are started up.

### Semiconductor Integrated Circuit Device (Second Embodiment)

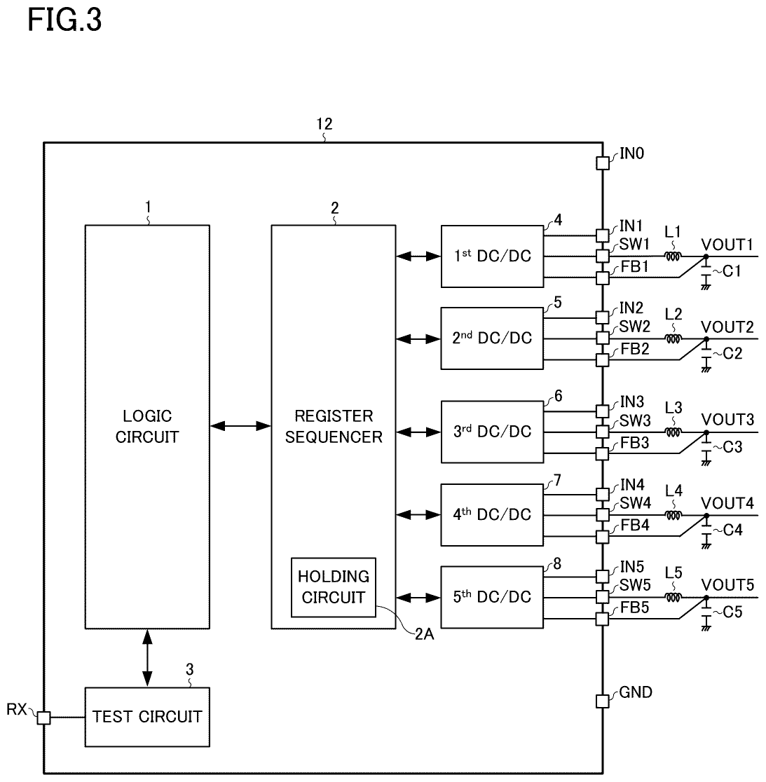

FIG. 3 is a block diagram showing a configuration of a semiconductor integrated circuit device according to a second embodiment. The semiconductor integrated circuit device 12 of this embodiment is, like the semiconductor integrated circuit device 11, a PMIC. In the semiconductor integrated circuit device 12, such parts as find their counterparts in the semiconductor integrated circuit device 11 are identified by common reference signs, and no overlapping description will be repeated.

The semiconductor integrated circuit device 12 has a terminal RX. The test circuit 3 receives an external signal received at the terminal RX.

Unlike the holding circuit 2A of the first embodiment, the holding circuit 2A of this embodiment, triggered by the reception of the external signal after the start-up of the semiconductor integrated circuit device 12, holds setting information output from the logic circuit 1.

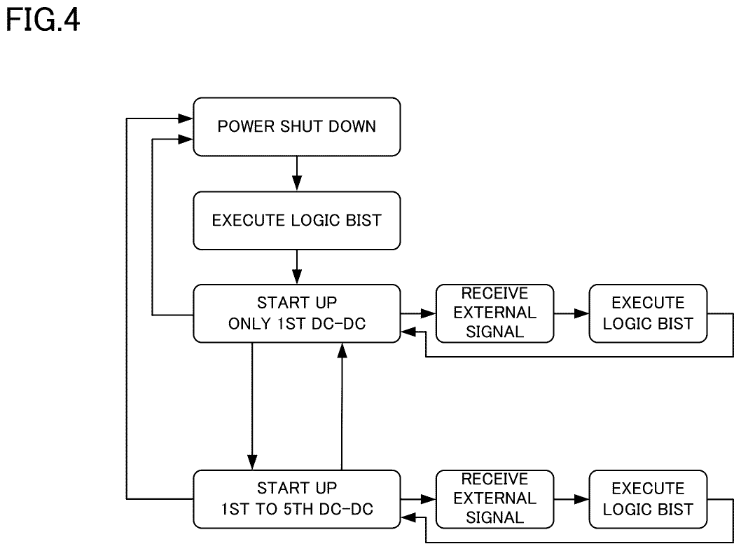

FIG. 4 is a diagram showing state transitions in the semiconductor integrated circuit device 12. Here, as one example, it is assumed that the semiconductor integrated circuit device 12 can, after its start-up, take two states: a state where only the first DC-DC converter 4 among the first to fifth DC-DC converters 4 to 8 is started up; and a state where all the first to fifth DC-DC converters 4 to 8 are started up.

When a transition is made from a state where the power is shut down (no input voltage is fed to the terminal IN0) to a state where the power is on (the input voltage is fed to the terminal IN0), the test circuit 3 executes a BIST on the logic circuit 1. After the BIST on the logic circuit 1 is complete, the start-up of the semiconductor integrated circuit device 12 is complete.

In the example shown in FIG. 4, after the BIST on the logic circuit 1 is complete, the semiconductor integrated circuit device 12 is in the state where only the first DC-DC converter 4 among the first to fifth DC-DC converters 4 to 8 is started up.

Then, under the control of the logic circuit 1, the semiconductor integrated circuit device 12 goes into either a state where only the first DC-DC converter 4 among the first to fifth DC-DC converters 4 to 8 is started up or a state where all the first to fifth DC-DC converters 4 to 8 are started up.

When, in the state where only the first DC-DC converter 4 among the first to fifth DC-DC converters 4 to 8 is started up, the semiconductor integrated circuit device 12 receives the external signal, the test circuit 3 executes the BIST on the logic circuit 1.

More specifically, when the semiconductor integrated circuit device 12 receives the external signal, triggered by it, the holding circuit 2A holds the setting information (the setting information in the state where only the first DC-DC converter 4 among the first to fifth DC-DC converters 4 to 8 is started up) output from the logic circuit 1. In this way, the semiconductor integrated circuit device 12 can continue to normally output the output voltage VOUT1 using the inductor L1 and the capacitor C1.

Then, after the setting information output from the logic circuit 1 is held by the holding circuit 2A, the test circuit 3 executes the BIST on the logic circuit 1. When the logic BIST is complete, the holding circuit 2A ceases to hold the setting information output from the logic circuit 1.

When, in the state where all the first to fifth DC-DC converters 4 to 8 are started up, the semiconductor integrated circuit device 12 receives the external signal, the test circuit 3 executes the BIST on the logic circuit 1.

More specifically, when the semiconductor integrated circuit device 12 receives the external signal, triggered by the reception of the external signal, the holding circuit 2A holds the setting information (the setting information in the state where all the first to fifth DC-DC converters 4 to 8 are started up) output from the logic circuit 1. As a result, the semiconductor integrated circuit device 12 can continue to normally output the output voltages VOUT1 to VOUT5 using the inductors L1 to L5 and the capacitors C1 to C5.

Then, after the setting information output from the logic circuit 1 is held by the holding circuit 2A, the test circuit 3 executes the BIST on the logic circuit 1. When the logic BIST is complete, the holding circuit 2A ceases to hold the setting information output from the logic circuit 1.

The semiconductor integrated circuit device 12 can increase the frequency of executing the logic BIST, and this helps improve reliability against faults. The semiconductor integrated circuit device 12 increases the frequency of executing the logic BIST in accordance with the reception of an external signal, and this helps increase flexibility in the timing of the logic BIST execution.

### Examples of Application of Semiconductor Integrated Circuit Device

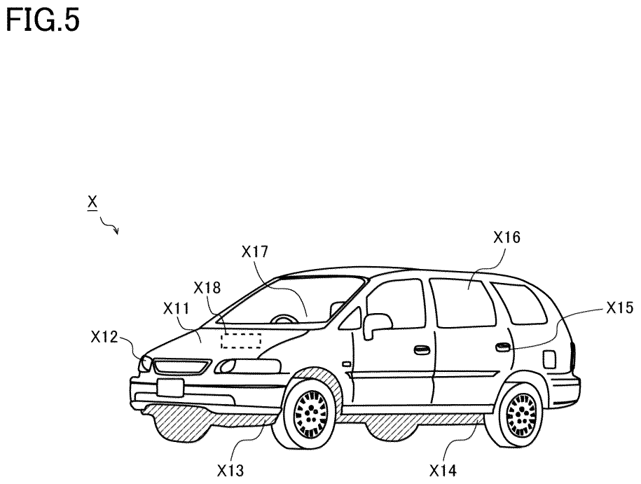

FIG. 5 is an exterior view of a vehicle X. The vehicle X shown in FIG. 5 incorporates various electronic appliances X11 to X18 that operate by being fed with a voltage output from an unillustrated battery. It should be noted that, for the sake of convenient illustration, FIG. 5 may show the electronic appliances X11 to X18 elsewhere than they are actually arranged.

The electronic appliance X11 is an engine control unit which performs control with respect to an engine (injection control, electronic throttle control, idling control, oxygen sensor heater control, automatic cruise control, etc.).

The electronic appliance X12 is a lamp control unit which controls the lighting and extinguishing of HIDs (high-intensity discharged lamps) and DRLs (daytime running lamps).

The electronic appliance X13 is a transmission control unit which performs control with respect to a transmission.

The electronic appliance X14 is a movement control unit which performs control with respect to the movement of the vehicle X (ABS [anti-lock brake system] control, electronic suspension control, etc.).

The electronic appliance X15 is a security control unit which drives and controls door locks, burglar alarms, and the like.

The electronic appliance X16 comprises electronic appliances incorporated in the vehicle X as standard or manufacturer-fitted equipment at the stage of factory shipment, such as wipers, power side mirrors, power windows, dampers (shock absorbers), a power sun roof, and power seats.

The electronic appliance X17 comprises electronic appliances fitted to the vehicle X optionally as user-fitted equipment, such as A/V (audio/visual) equipment, a car navigation system, an ETC (electronic toll collection system), and a vehicle-mounted camera module.

The electronic appliance X18 comprises electronic appliances provided with high-withstand-voltage motors, such as EPS (electric power steering), a vehicle-mounted blower, an oil pump, a water pump, and a battery cooling fan.

The semiconductor integrated circuit device described above can be incorporated into any of the electronic appliances X11 to X18.

The embodiments disclosed herein should be considered to be in every aspect illustrative and not restrictive, and the technical scope of the disclosure herein is defined not by the description of embodiments given above but by the scope of the appended claims and should be understood to encompass any modifications within a sense and scope equivalent to the claims.

For example, the first and second embodiments described above can be implemented in combination. That is, the holding circuit may be configured to hold the setting information output from the logic circuit both when triggered by a state transition after the start-up of the semiconductor integrated circuit device and when triggered by the reception of an external signal.

For example, while the semiconductor integrated circuit device described previously is a PMIC, the disclosure herein can also be applied to semiconductor integrated circuit devices other than power supply devices so long as they are configured to include a logic circuit.

According to one aspect of what is disclosed herein, a semiconductor integrated circuit device (11, 12) includes a logic circuit (1), a holding circuit (2A) configured to hold setting information output from the logic circuit when triggered by an event after the start-up of the semiconductor integrated circuit device, and a test circuit (3) configured to execute a BIST on the logic circuit after completion of the holding. (A first configuration.)

The semiconductor integrated circuit device according to the first configuration described above can increase the frequency of executing the logic BIST, and this helps improve reliability against faults.

In the semiconductor integrated circuit device according to the first configuration described above, preferably, the event is a state transition. (A second configuration.)

The semiconductor integrated circuit device according to the second configuration described above can increase the frequency of executing the logic BIST in accordance with state transitions.

In the semiconductor integrated circuit device according to the second configuration described above, preferably, the state transition is a transition between a first state and a second state from one to the other, and the second state is a state where the number of power supply circuits that are started up is larger than in the first state. (A third configuration.)

The semiconductor integrated circuit device according to the third configuration described above can increase the frequency of executing the logic BIST in accordance with changes in the number of power supply circuits that are started up.

In the semiconductor integrated circuit device according to the third configuration described above, preferably, the second state is a state where all the plurality of power supply circuits are started up. (A fourth configuration.)

The semiconductor integrated circuit device according to the fourth configuration described above can increase the frequency of executing the logic BIST when a transition to a state where all of the plurality of power supply circuits are started up takes place frequently.

In the semiconductor integrated circuit device according to the third or fourth configuration described above, preferably, the test circuit is configured to execute the logic BIST every time a state transition is made between the first and second states from one to the other. (A fifth configuration.)

The semiconductor integrated circuit device according to the fifth configuration described above can further increase the frequency of executing the logic BIST.

In the semiconductor integrated circuit device according to the third or fourth configuration described above, preferably, the test circuit is configured to execute the logic BIST some of times that a state transition is made between the first and second states from one to the other. (A sixth configuration.)

The semiconductor integrated circuit device according to the sixth configuration described above can adjust the frequency of executing the logic BIST.

In the semiconductor integrated circuit device according to the first configuration described above, preferably, the event is the reception of an external signal (a seventh configuration.)

The semiconductor integrated circuit device according to the seventh configuration described above can increase the frequency of executing the logic BIST in accordance with the reception on an external signal. Thus, it is possible to increase the flexibility in the timing of executing the logic BIST.

According to another aspect of what is disclosed herein, a vehicle-mounted appliance (X11 to X18) includes the semiconductor integrated circuit device according to any of the first to seventh configurations described above. (An eighth configuration.)

The vehicle-mounted appliance according to the eighth configuration described above can increase reliability against faults in the semiconductor integrated circuit device.

According to yet another aspect of what is described herein, a vehicle (X) includes the vehicle-mounted appliance according to the eighth configuration described above (A ninth configuration.)

The vehicle according to the ninth configuration described above can increase reliability against faults in the semiconductor integrated circuit device.

What is claimed is:

1. A semiconductor integrated circuit device having a logic circuit, comprising:
a holding circuit configured to hold setting information output from the logic circuit when triggered by an event after start-up of the semiconductor integrated circuit device; and
a test circuit configured to execute a BIST on the logic circuit after completion of the holding.

2. The semiconductor integrated circuit device according to claim 1,
wherein
the event is a state transition.

3. The semiconductor integrated circuit device according to claim 2, further comprising a plurality of power supply circuits,
wherein
the state transition is a transition between a first state and a second state from one to another, and
the second state is a state where a number of power supply circuits that are started up is larger than in the first state.

4. The semiconductor integrated circuit device according to claim 3,
wherein
the second state is a state where all the plurality of power supply circuits are started up.

5. The semiconductor integrated circuit device according to claim 3,
wherein
the test circuit is configured to execute the logic BIST every time a state transition is made between the first and second states from one to another.

6. The semiconductor integrated circuit device according to claim 4,
wherein
the test circuit is configured to execute the logic BIST every time a state transition is made between the first and second states from one to another.

7. The semiconductor integrated circuit device according to claim 3,
wherein
the test circuit is configured to execute the logic BIST some of times that a state transition is made between the first and second states from one to another.

8. The semiconductor integrated circuit device according to claim 4,
wherein
the test circuit is configured to execute the logic BIST some of times that a state transition is made between the first and second states from one to another.

9. The semiconductor integrated circuit device according to claim 1,
wherein
the event is reception of an external signal.

10. A vehicle-mounted appliance comprising the semiconductor integrated circuit device according to claim 1.

11. A vehicle comprising the vehicle-mounted appliance according to claim 10.
